(19) United States
(12) Patent Application Publication
(10) Pub. No.: US 2012/0106052 A1
(43) Pub. Date: May 3, 2012

(54) TWIN-MATE CPU ASSEMBLY

(76) Inventors: Robert D. Odineal, Roseville, CA (US); Naysen Robertson, Orangevale, CA (US); Kenneth N. Konesky, North Highlands, CA (US)

(21) Appl. No.: 12/915,237

(22) Filed: Oct. 29, 2010

(51) Int. Cl. G06F 1/16; H05K 3/36

(52) U.S. Cl. 361/679.02; 29/830

(57) ABSTRACT

An assembly includes a first central-processor-unit (CPU) printed-circuit board (PCB). The PCB is configured to accept a first processor set of processors mounted thereon. In addition, a first twin-mate arrangement of connectors is mounted on said first CPU PCB.

### BACKGROUND

Systems with different numbers of processors can provide for a range in computing power. For example, a particular processor may be used by itself or as part of a CPU assembly including four processors. A pair of CPU assemblies can be mated to provide eight processors. Several CPU assemblies can be mounted in a backplane to providing even higher levels of computing power.

Economies of scale can be met using a single processor design that permits various configurations such as those mentioned above. A single processor design can be incorporated in different CPU assemblies (e.g., with different numbers of CPUs, different printed-circuit boards and support circuitry, and different connectors) to provide computing systems representing a range of performance specifications.

For example, a processor can be designed to support both glued and glueless configurations. In a “glued” configuration, “glue” logic external to the processors is provided through which the processors or processor assemblies communicate with each other. The glue logic can provide various functions, such as snoop filtering, that enhance inter-processor communications, especially in large-scale systems. In glueless systems, CPU's or CPU assemblies communicate directly without intervening logic. Typically, glueless systems are less costly, while glued systems are better suited to large-scale systems.

### BRIEF DESCRIPTION OF THE DRAWINGS

FIG. 1 is a schematic diagram of an assembly in accordance with an embodiment

FIG. 2 is a flow chart of a process in accordance with an embodiment.

FIG. 3 is a flow chart of a process in accordance with another embodiment.

FIG. 4 is a schematic bottom plan view of a CPU assembly resulting from a process segment of the process of FIG. 3. In FIG. 4, dashed lines correspond to components on the side of a PCB facing opposite the reader.

FIG. 5 is a schematic elevation view of a pair of CPU assemblies resulting from a process segment of the process of FIG. 3. Some components shown in FIG. 4 are omitted from FIG. 5 for the sake of clarity.

FIG. 6 is a schematic elevational view of the pair of CPU assemblies of FIG. 5 after they have been mated in accordance with a process segment of the process of FIG. 3.

FIG. 7 is a schematic elevational view of a glued CPU module.

FIG. 8 is a schematic view of a computer system including a backplane with several CPU modules connected thereto.

FIG. 9 is a schematic view of a CPU module including two CPU PCA assemblies and a glue-logic PCA assembly.

### DETAILED DESCRIPTION

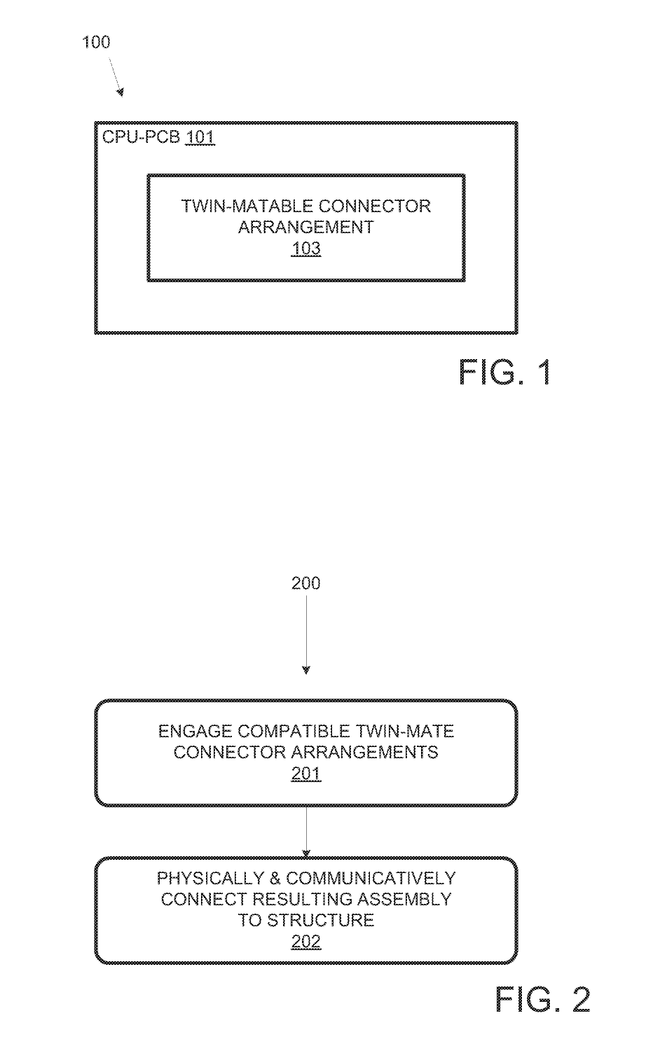

An assembly 100 includes a central-processing unit (CPU) printed-circuit-board (PCB) 101 and a twin-mate connector arrangement 103, as shown in FIG. 1. Herein, “twin-mate” characterizes an object that is configured to mate with a copy of itself even if it is, in fact, to be mated with some other object). Thus, process 200, flow charted in FIG. 2, provides for assembling a glueless CPU module at process segment 201 by mating two CPU printed-circuit assemblies (CPAs). Alternatively, process segment 201 provides for assembling a glue-logic module by mating a twin-mate CPU CPA with a twin-mate glue-logic CPA. Thus, economies of scale can be realized by using a single CPU CPA design for both glued and glueless configurations. In either case, once it is assembled, a glued or glueless CPU module can be physically and communicatively connected to a structure such as a motherboard or backplane at process segment 202.

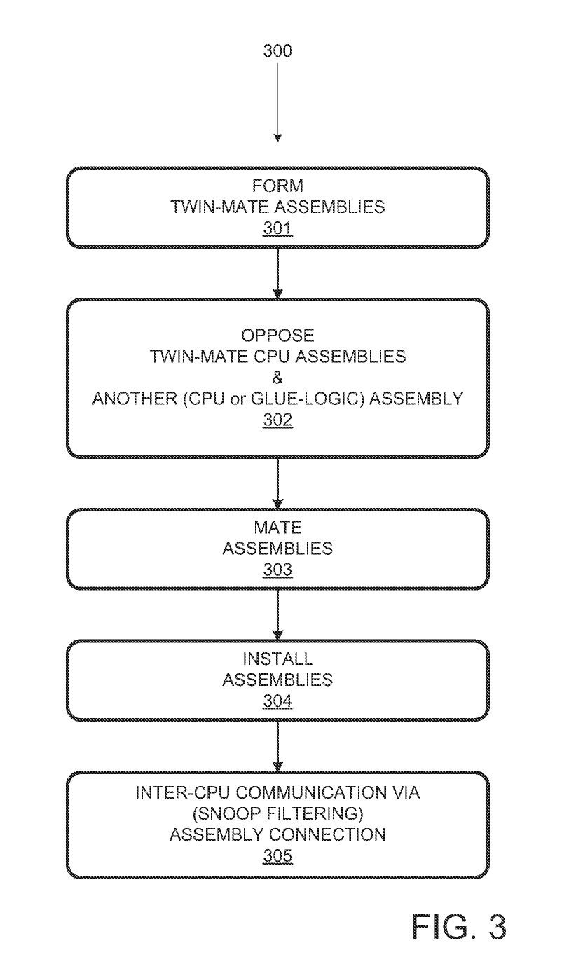

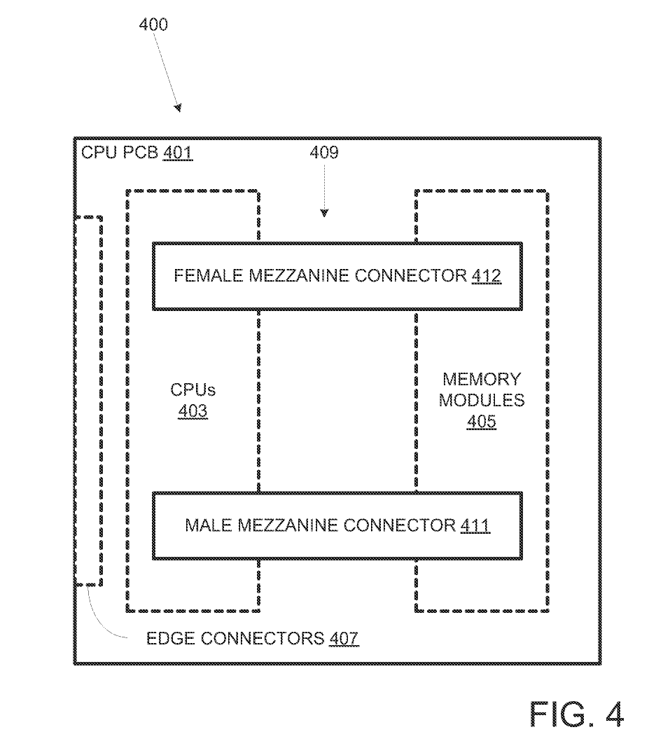

A process 300, flow-charted in FIG. 3, provides for forming twin-mate assemblies at process segment 301. Process segment 401 can result in an assembly such a CPU PCA 400 of FIG. 4. CPU CPA 400 includes a CPU PCB 301, processors 303, memory modules 305, a set of edge connectors 307, and a twin-mate arrangement 309 of male and female mezzanine connectors 311 and 312. (Note that, herein, “processor” and “CPU” are synonymous and refer to a hardware device for processing physically encoded computer instructions.) Alternatively, the resulting CPU CPA can be provided initially without processors or memory, which can added later. Also, process segment 301 provides for assembly glue-logic PCA's, to be described below.

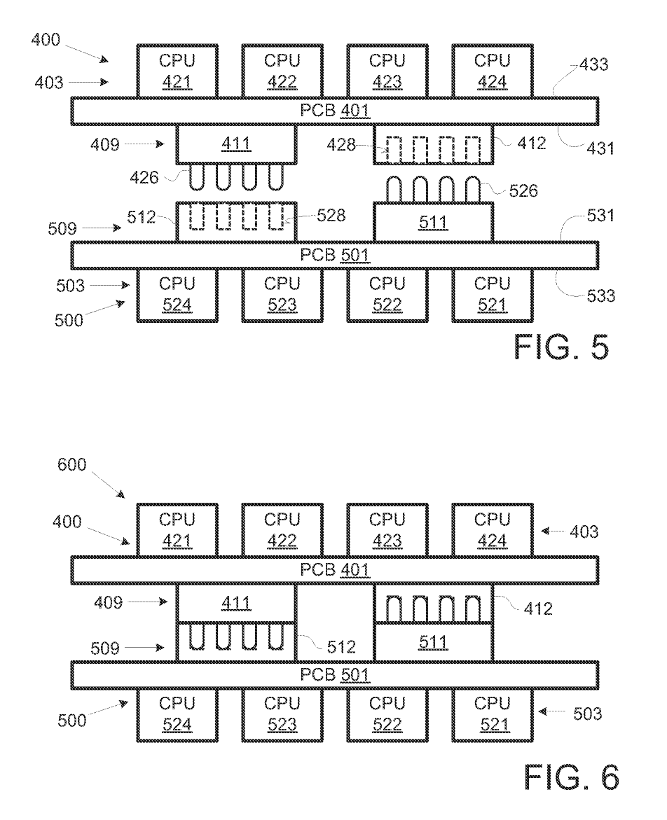

At process segment 302, a pair of twin-mate assemblies can be opposed (disposed opposite each other). In the case of CPU PCA 400, twin-mate connectors 411 and 412 are mounted on a bottom face of CPU PCB 401, whereas processors 403, memory modules 405, and edge connector set 407 are mounted on a top face of CPU PCB 401. As indicated in FIG. 5, process segment 302 provides for a pair of twin-mate CPU PCAs 400 and 500 to be disposed with their bottom faces 431 and 531 facing each other and the top faces 433 and 533 facing away from each other.

In FIG. 5, CPU PCA 400 is shown including PCB 401, processors 421, 422, 423, and 424 of processor set 403, and male and female mezzanine connectors 411 and 412, respectively, of twin-mate arrangement 409. Male connector 411 has pins 426 and female connector 412 has complementary sockets 428. CPU PCA 500 is shown including PCB 501, processors 521-524 of processor set 503, male and female mezzanine connectors 511 and 512 of a twin-mate arrangement 509. Male connector 511 has pins 526 while female connector 512 has complementary sockets 528.

In the configuration of FIG. 5, male connector 411 is disposed opposite female connector 512, and female connector 412 opposes male connector 511. Thus, at process segment 303, FIG. 3, CPU PCAs can be mated by moving CPU PCAs 400 and 500 relatively toward each other orthogonally to the planes of PCBs 401 and 402, resulting in a CPU module 600, shown in FIG. 6. Herein, “module” is used to refer to an assembly of PCAs.

CPU PCA 400 is an exemplar of one type of twin-mate connector arrangement. In this type of arrangement, one or more male-female pairs of connectors are arranged with 180 degree anti-symmetry so that opposing pairs of male and female connectors can mate when two twin-mate connector arrangements are disposed facing each other. Herein, “anti-symmetry” refers to the condition in which a 180 degree rotation results in the male connector assuming the former position of the female connector and vice versa. In a related arrangement, each “hermaphrodite” connector has both male and female features so that connectors can twin-mate on a connector-by-connector basis. In some embodiments, twinning can involve stackable connectors, in which case mating can occur without disposing assemblies in opposing orientations.

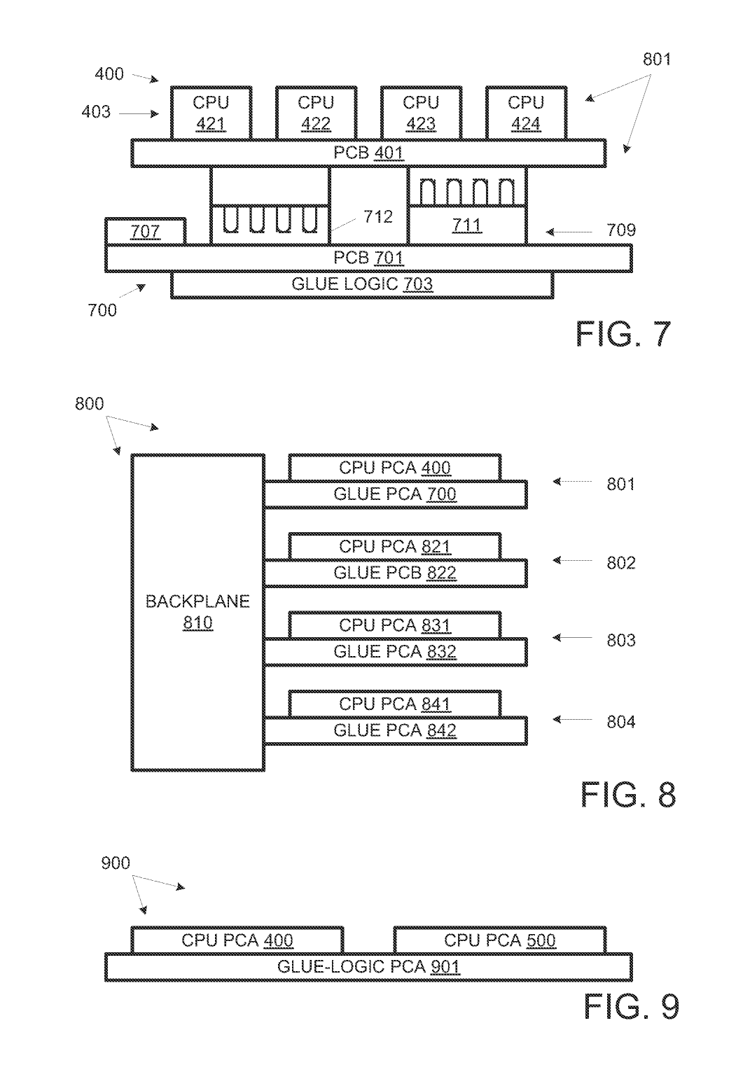

While CPU PCA assemblies 400 and 500 are nominally identical, in other embodiments, twin-mate CPU PCAs with different specifications (e.g., different numbers and types of processors and memory modules) can be mated. Also, one twin-mate CPU PCA can be mated with an assembly other than a CPU PCA. In particular, process segment 303 can involve mating a twin-mate CPU PCA 400 with a glue-logic PCA 700, as shown in FIG. 7, to yield a glued CPA module 801.

Glue-logic PCA 700 includes a glue-logic PCB 701, glue logic 703, an edge connector set 707, and a mezzanine edge-connector arrangement 709 including male and female twin-mate mezzanine connectors 711 and 712. Glue logic 703 is configured to intercept signals travelling between CPUs 403 and edge connector 707. Glue logic can buffer signals to overcome attenuation. In addition, signals can be processed by glue logic 703. For example, glue logic 703 can inspect through going signals to determine contents of memory modules 405 (FIG. 4). Glue logic 703 can then respond to some inquiries regarding the contents of memory modules 405; the requests can then be filtered, e.g., prevented from continuing to CPUs 403, thereby reducing inter-CPU traffic. This filtering can mitigate the amount of cache snooping require for systems with large numbers of CPUs.

Several glued CPA modules 801, 802, 803, and 804 can be inserted into a backplane 810 to define a multi-processor computer system 800, shown in FIG. 8. Backplane 810 provides for inter-module communications and thus inter-processor communications among modules 801-804. In alternative embodiments, a computer system can have different backplane configurations with different capacities in terms of the number of CPU modules that can be inserted. Also, a backplane can be fully or partially populated with CPU modules.

In computer system 800, CPU modules 801-804 are connected to backplane 810 via edge connectors, e.g., edge connector 707. There is no direct connection between a CPU PCB and backplane 810. According, edge connectors, e.g., edge connector 407, FIG. 4, on CPU PCAs are not used in this configuration and can be omitted from the CPU PCAs to provide further cost savings. Whether or not the unused edge connectors are in place or omitted, the respective CPU PCBs used for glued and glueless systems can be identical to achieve economies of scale.

Another glued CPA module configuration is shown in FIG. 9. Plural CPU PCAs 400 and 500 are mounted on the same glue-logic PCA 901 to define a CPU module 900. Glue-logic PCA 901 includes plural sets of twin-mate connector arrangements to accommodate plural CPU PCAs. Glue-logic PCA 901 can be, for example, a motherboard or a daughterboard. In another embodiment, two CPU PCAs are attached to opposite sides of a glue-logic PCA forming a glue-logic CPA sandwich. Those skilled in the art can apply the foregoing teachings to provide a variety of other configurations.

Herein, a “connector” is a physical device configured for physical and communicative mating with a compatible connector. Connectors are typically incorporated into respective host devices (e.g., a PCA assembly) so that mating connectors mates the host devices. “Communicative” and related terms encompass electrical and optical communications. In other words, mating connectors can provide for conveyance of electrical signals, optical signals, or both.

Herein, a “mezzanine” connector is a connector mounted on a face of a PCB board or other substrate and oriented to provide for a mating motion orthogonal to a plane of the PCB board. An edge connector is a connector, typically mounted on or near an edge of a PCB board, that is oriented to provide for a mating motion along the place of a PCB board.

Herein, “glue” refers to glue-logic circuitry for monitoring and in some cases modifying communications passing therethrough between processors and other computing devices. A glued module is one in which processors communicate with external processes of a multiprocessor system via glue logic. A glueless module is a module in which processors on different CPAs of the module communicate with each other directly and not through glue logic.

Herein, a “processor”, “central-processing unit”, or “CPU” is an integrated circuit or integrated circuit package for executing physically encoded computer instructions. “Memory” is non-transitory tangible computer-readable storage media. A printed circuit board is used to mechanically support and electrically connect electronic components, such as processors and memory modules, using conductive pathways, tracks or signal traces, e.g., etched from copper sheets laminated onto a non-conductive substrate.

Herein, A “backplane” (or “backplane system”) is a circuit board (usually a printed circuit board) that connects several connectors in parallel to each other so that each pin of each connector is linked to the same relative pin of all the other connectors forming a computer bus. A back plane can be used as a backbone to connect several printed circuit boards together to make up a complete computer system. A backplane is generally differentiated from a motherboard by the lack of on-board processing power where the CPU is on a plug-in card.

Herein, a “system” is a set of interacting elements, wherein the elements can be, by way of example and not of limitation, mechanical components, electrical elements, atoms, instructions encoded in storage media, and process segments. In this specification, related art is discussed for expository purposes. Related art labeled “prior art”, if any, is admitted prior art. Related art not labeled “prior art” is not admitted prior art. The illustrated and other described embodiments, as well as modifications thereto and variations thereupon are within the scope of the following claims.

What is claimed is:

1. An assembly comprising:
a first central-processor-unit (CPU) printed-circuit board (PCB) configured to accept a first processor set of processors mounted thereon; and
a first twin-mate arrangement including at least one connector on said first CPU PCB.

2. An assembly as recited in claim 2 further comprising said first processor set mounted on said first CPU PCB.

3. An assembly as recited in claim 2 further comprising:
a second CPU PCB;
a second processor set mounted on said second CPU PCB; and
a second twin-mate arrangement of connectors mounted on said second CPU PCB and mated to said first twin-mate arrangement.

4. An assembly as recited in claim 2 further comprising:
a first glue-logic PCB;
first glue logic mounted on said first glue-logic PCB;
a first edge arrangement of edge connectors mounted on an edge of said glue-logic PCB; and
a second twin-mate arrangement of connectors mounted on said glue-logic PCB and mated to the connectors of said first twin-mate arrangement.

5. An assembly as recited in claim 4 further comprising:
a third twin-mate arrangement of connectors mounted on said glue-logic PCB;
a second CPU PCB;
a second processor set mounted on said second CPU PCB; and
a fourth twin-mate arrangement of connectors mounted on said second CPU PCB and engaged with said third twin-mate arrangement.

6. An assembly as recited in claim 4 further comprising:
a backplane configured to mate with plural CPU modules and to provide for communications among said CPU modules; and
said CPU modules), each of said CPU modules including
a respective CPU PCA with a respective processor set and a respective twin-mate arrangement of connectors mounted thereon, and
a respective glue-logic PCA with respective glue logic, a respective edge arrangement of edge connectors, and a respective twin-mate arrangement of connectors mounted thereon and mated to the respective twin-mate arrangement of the respective CPU PCA;
one of said CPU modules including said first CPU PCB, said first glue-logic PCB, said first processor set, said first and second twin-mate arrangements, said first edge arrangement, and said first glue logic.

7. An assembly as recited in claim 1 wherein said first twin-mate arrangement is a mezzanine arrangement of mezzanine connectors.

8. An assembly as recited in claim 7 further comprising a first edge arrangement of edge connectors mounted on or at an edge of said CPU PCB.

9. A process comprising:
engaging compatible twin-mate arrangements of connectors so as to attach a first CPU printed-circuit assembly (PCA) to another PCA; and
physically and communicatively connecting the resulting assembly to a structure via an edge connector of one of said PCAs.

10. A process as recited in claim 9 wherein said another PCA is another CPU PCA, said resulting assembly being glueless.

11. A process as recited in claim 9 wherein said another PCA is a glue-logic PCA including said edge connector.

12. A process as recited in claim 11 wherein said structure is a backplane.

13. A process as recited in claim 12 wherein said physically and communicatively connecting includes additional physically and communicatively connecting assemblies including twin-mate connectors to said backplane so that said assemblies can communicate with each other via said backplane

14. A process as recited in claim 13 further comprising a CPU on said first CPU PCA communicating with another CPU on said another CPU PCA via said backplane.

15. A process as recited in claim 14 wherein said communicating involves glue logic on said glue-logic PCA filtering cache snoops.
